(19) United States
(12) Patent Application Publication
(10) Pub. No.: US 2013/0316536 A1
(43) Pub. Date: Nov. 28, 2013

(54) SEMICONDUCTOR MANUFACTURING DEVICE AND SEMICONDUCTOR DEVICE MANUFACTURING METHOD

(71) Applicant: KABUSHIKI KAISHA TOSHIBA, Tokyo (JP)

(72) Inventors: Satoshi SETO, Kamakura-shi (JP); Hideaki HARAKAWA, Gifu-shi (JP)

(21) Appl. No.: 13/781,377

(22) Filed: Feb. 28, 2013

(30) Foreign Application Priority Data
May 22, 2012 (JP) 2012-116783

(51) Int. Cl. H01L 21/263

(52) U.S. Cl. CPC H01L 21/2633
USPC 438/689; 156/345.51

(57) ABSTRACT

A semiconductor manufacturing apparatus according to an embodiment includes a stage capable of mounting a semiconductor substrate thereon, a first irradiation part configured to irradiate an etching beam onto the semiconductor substrate from a first direction inclined at an arbitrary angle with respect to a vertical direction to a surface of the semiconductor substrate, and a second irradiation part configured to irradiate an etching beam onto the semiconductor substrate from a second direction inclined at an arbitrary angle with respect to the vertical direction. The first and second irradiation parts simultaneously irradiate the etching beams when processing the semiconductor substrate or a material on the semiconductor substrate.

### CROSS REFERENCE TO RELATED APPLICATIONS

This application is based upon and claims the benefit of priority from the prior Japanese Patent Application No. 2012-116783, filed on May 22, 2012, the entire contents of which are incorporated herein by reference.

### FIELD

The embodiments of the present invention relate to a semiconductor manufacturing apparatus and manufacturing method of a semiconductor device.

### BACKGROUND

There is known a magnetic random access memory (MRAM) as one type of a resistance change memory. The MRAM includes MTJ (Magnetic Tunnel Junction) elements using a TMR (Tunneling Magnetoresistive) effect as storage elements.

An MTJ element of a spin-transfer torque writing type has a stacked structure in which a nonmagnetic barrier layer (an insulating thin film) is sandwiched between two ferromagnetic layers (a recording layer and a pinned layer), and stores digital data by the change in a magnetic resistance due to the spin-polarized tunneling effect. Data is written by applying a current in a stacking direction of the MTJ element.

Generally, at a time of forming such an MTJ element, the two ferromagnetic layers and the nonmagnetic barrier layer are etched at a time. As a method of processing the MTJ element, IBE (Ion Beam Etching) is used. Because the IBE is physical etching, etched materials sometimes recoil and get re-deposited on a sidewall of the MTJ element. When a conductive material is re-deposited on a side surface of the MTJ element, a short pass is disadvantageously formed between the recording layer and the pinned layer.

To suppress the formation of such a short pass, it is conceivable to incline IBE etching beams with respect to a perpendicular direction to a top surface of a semiconductor substrate. This can increase components of side etching to the side surface of the MTJ element and can remove re-deposition materials from the side surface thereof.

However, when the density of MTJ elements rises on a flat layout, the distance between adjacent MTJ elements is reduced (aspect ratio increases). Accordingly, if the etching beams are inclined, one of the two adjacent MTJ elements is hidden behind the other MTJ element, and the etching beams are unable to be irradiated on the side surface of the former MTJ element. In this case, re-deposition materials remain on the side surface of the MTJ element, which possibly causes the short pass.

### BRIEF DESCRIPTION OF THE DRAWINGS

FIG. 1 is a schematic diagram showing a configuration of an etching apparatus according to a first embodiment;

FIG. 2 is a schematic plan view showing the etching apparatus 100 as seen from above;

FIG. 3 is a conceptual diagram showing a positional relation between the first and second ion guns 20 and 30;

FIGS. 4A and 4B show a relation between an arrangement after forming two adjacent MTJ elements and a critical angle θcrt of ion beams;

FIG. 5 is a plan view showing a layout of the MTJ elements and the hard masks HM and irradiating directions of the ion beams IB1 and IB2;

FIGS. 6A to 6D are cross-sectional views showing a formation flow of each of the MTJ elements using the etching apparatus 100 according to the first embodiment;

FIGS. 7A to 7C and 8A to 8C are cross-sectional views showing a formation flow of each MTJ element using an etching apparatus according to a comparative example;

FIGS. 9A and 9B are plan views showing the layout of MTJ elements and hard masks HM and irradiating directions of the ion beams IB1 and IB2 according to a second embodiment;

FIG. 10 is a schematic plan view showing the etching apparatus 100 as seen from above according to a third embodiment;

FIG. 11 is a conceptual diagram showing a positional relation among the first to third ion guns 20, 30, and 95; and

FIG. 12 is a plan view showing irradiating directions of the ion beams IB1 to IB3.

### DETAILED DESCRIPTION

A semiconductor manufacturing apparatus according to an embodiment comprises a stage capable of mounting a semiconductor substrate thereon, a first irradiation part configured to irradiate an etching beam onto the semiconductor substrate from a first direction inclined at an arbitrary angle with respect to a vertical direction to a surface of the semiconductor substrate, and a second irradiation part configured to irradiate an etching beam onto the semiconductor substrate from a second direction inclined at an arbitrary angle with respect to the vertical direction. The first and second irradiation parts simultaneously irradiate the etching beams when processing the semiconductor substrate or a material on the semiconductor substrate.

Embodiments will now be explained with reference to the accompanying drawings. The present invention is not limited to the embodiments.

### First Embodiment

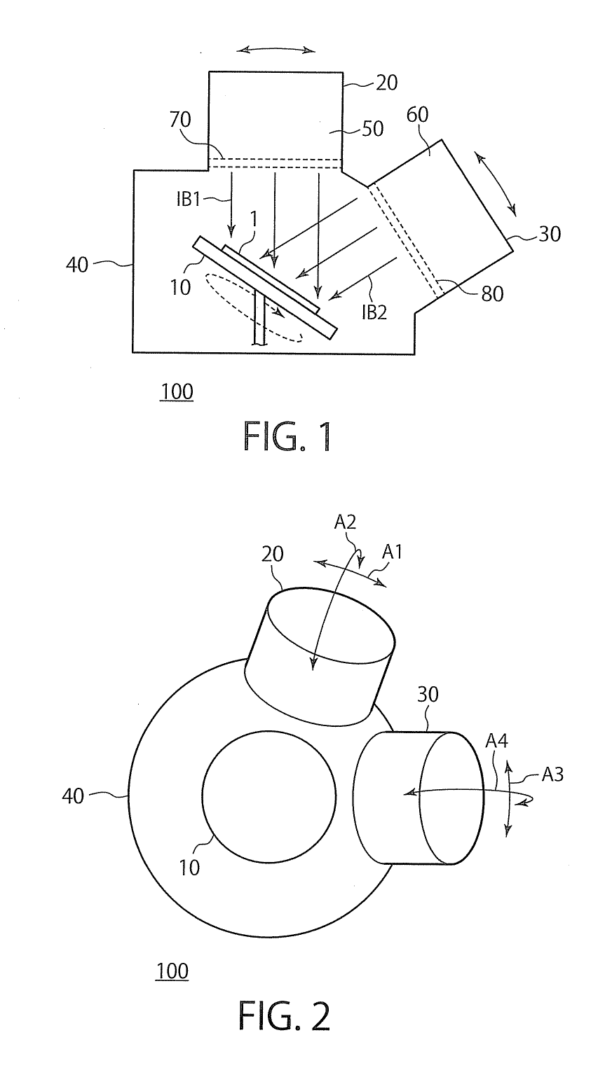

FIG. 1 is a schematic diagram showing a configuration of an etching apparatus according to a first embodiment. An etching apparatus 100 serving as a semiconductor manufacturing apparatus is, for example, an IBE (Ion Beam Etching) apparatus. The etching apparatus 100 includes a stage 10 on which a semiconductor substrate 1 can be mounted, a first ion gun 20 that irradiates etching beams IB1 onto the semiconductor substrate 1, and a second ion gun 30 that irradiates etching beams IB2 onto the semiconductor substrate 1. For example, an MRAM (Magnetic Random Access Memory) can be formed on the semiconductor substrate 1.

The stage 10 is arranged within a chamber 40. The stage 10 can be inclined with respect to irradiating directions of the etching beams IB1 and IB2 irradiated from the first and second ion guns 20 and 30, respectively in a state of mounting the semiconductor substrate 1 on the stage 10, and can rotate the semiconductor substrate 1 while being kept inclined.

The first and second ion guns 20 and 30 generate ion plasmas from ion sources provided in bell jars 50 and 60, respectively. Ions are accelerated to predetermined accelerations by grids 70 and 80 to which electric fields are applied, and irradiated toward the semiconductor substrate 1 on the stage 10 as the directional ion beams IB1 and IB2, respectively. The ion beams IB1 and IB2 thereby etch the semiconductor substrate 1 or materials deposited on the semiconductor substrate 1 by physical sputtering. For example, inert gas such as Ar, Kr, or Xe, gas such as O or N, or molecular clusters consisting of these substances are used as the ion beams IB1 and IB2.

FIG. 2 is a schematic plan view showing the etching apparatus 100 as seen from above. The first and second ion guns 20 and 30 are provided to be movable along the chamber 40 as indicated by arrows A1 to A4. The first and second ion guns 20 and 30 can thereby irradiate the ion beams IB1 and IB2 onto the semiconductor substrate 1 on the stage 10 from various directions.

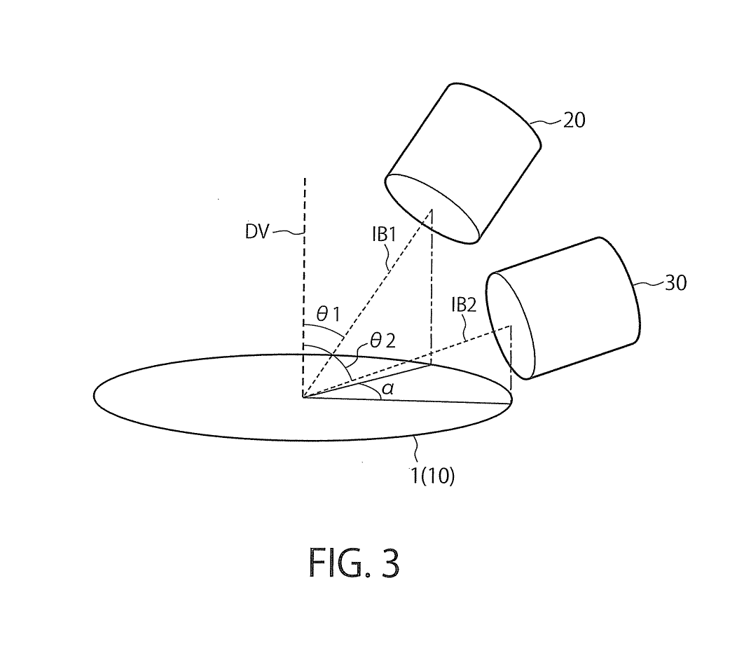

FIG. 3 is a conceptual diagram showing a positional relation between the first and second ion guns 20 and 30. The first ion gun 20 irradiates the etching beam IB1 onto the semiconductor substrate 1 from a first direction inclined at a first incident angle θ1 with respect to a vertical direction DV to a surface of the semiconductor substrate 1. The first incident angle θ1 can be set arbitrarily depending on an inclination angle of the stage 10 and a position of the first ion gun 20.

The second ion gun 30 irradiates the etching beam IB2 onto the semiconductor substrate 1 from a second direction inclined at a second incident angle θ2 with respect to the vertical direction DV to the surface of the semiconductor substrate 1. The second incident angle θ2 can be set arbitrarily depending on the inclination angle of the stage 10 and a position of the second ion gun 30.

The first and second incident angles θ1 and θ2 indicate opening angles from the vertical direction DV with respect to the vertical direction DV to the surface of the semiconductor substrate 1. Therefore, the first and second incident angles θ1 and θ2 can be set arbitrarily in a range from 0 to 90 degrees.

Furthermore, it is assumed here that a relative angle formed between the projection in the first direction and that of the second direction is α, when projecting the direction of the etching beam IB1 from the first ion gun 20 (a first direction) onto the semiconductor substrate 1 (or the stage 10) and the direction of the etching beam IB2 from the second ion gun 30 (a second direction) onto the semiconductor substrate 1 (or the stage 10).

The first and second incident angles θ1 and θ2 and the relative angle α can be set arbitrarily. The first incident angle θ1 can be set depending on the inclination angle of the stage 10 and the direction of the first ion gun 20. The second incident angle θ2 can be set depending on the inclination angle of the stage 10 and the direction of the second ion gun 30. The relative angle α can be set depending on relative positions of the first ion gun 20 and the second ion gun 30.

The first direction and the second direction do not perfectly mach each other. Accordingly, the first incident angle θ1 differs from the second incident angle θ2 (θ1≠θ2) or the relative angle α is not zero (α≠0).

Furthermore, the first and second ion guns 20 and 30 can set accelerating voltages and quantities of the etching beams IB1 and IB2 individually.

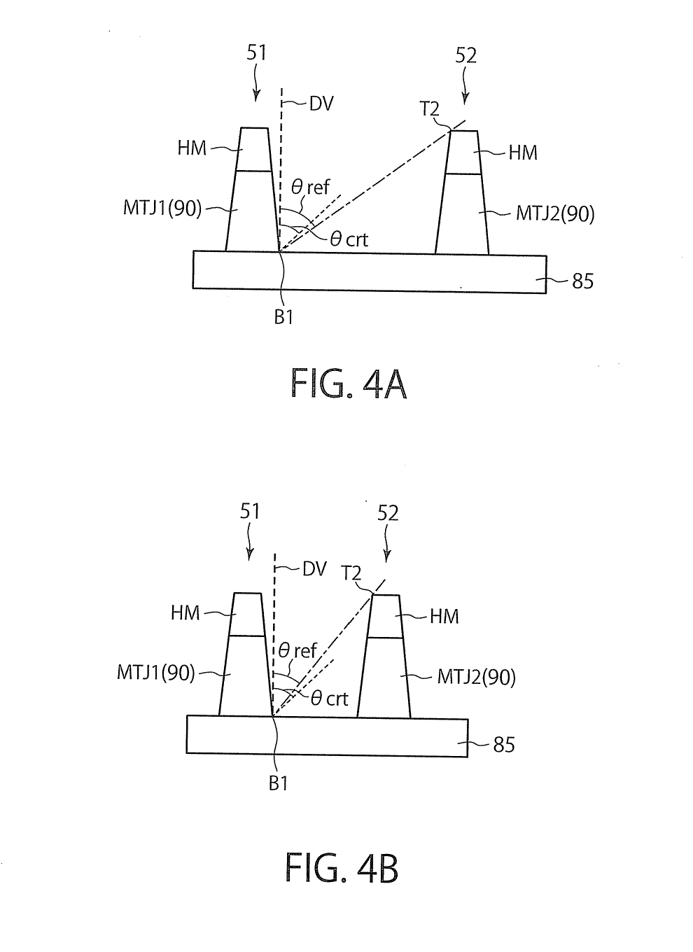

FIGS. 4A and 4B show a relation between an arrangement after forming two adjacent MTJ elements and a critical angle θcrt of ion beams.

First, the critical angle θcrt is explained. Generally, an etched material does not volatize but scatters in the air and re-deposits on a hard mask and a sidewall of each of the MTJ elements when the MTJ element is processed, because the IBE is the physical etching. For example, such re-deposition material is a ferromagnetic material of the MTJ element and has an electric conductivity. Accordingly, the re-deposition material causes a short pass between a recording layer and a pinned layer of the MTJ element. It is possibly proposed to increase the incident angle of the ion beams so as to remove the re-deposition material.

When the incident angle of the ion beams is set greater than a predetermined critical angle θcrt, etching components to a side surface of each MTJ element become larger in quantity than those to a top surface of materials of the MTJ element. This makes it possible to remove the re-deposition material (a re-deposition substance) adhering to the side surface of the MTJ element while etching the top surface of the materials of the MTJ element. However, side etching makes the MTJ element thinner.

On the other hand, when the incident angle of the ion beams is set smaller than the predetermined critical angle θcrt, the etching components to the side surface of each MTJ element become smaller in quantity than those to the top surface of the materials of the MTJ element. Therefore, the re-deposition material adhering to the side surface of the MTJ element remains.

For example, when the critical angle θcrt is about 45 degrees and the incident angle of the ion beams is smaller than the critical angle θcrt (e.g. about 45 degrees), the re-deposition material remains on the side surface of each MTJ element. If the incident angle of the ion beams is greater than the critical angle θcrt (e.g. about 45 degrees), the re-deposition material is removed from the side surface of the MTJ element, but the MTJ element becomes smaller because of an increase in side etching components. That is, the critical angle θcrt is an incident angle of the ion beams when the speed of deposition of the re-deposition material is substantially equal to that of removal of the re-deposition material. When the incident angle of the ion beams is substantially equal to the critical angle θcrt, it is possible to minimize the side etching to the side surface of the MTJ element while suppressing the re-deposition material from adhering to the sidewall of the MTJ element. In above embodiment, the value of 45 degrees of the critical angle θcrt is taken as an example, and the value of the critical angle θcrt is practically variable depending on various circumstances.

Meanwhile, when the density of the MTJ elements increases, the distance between the adjacent MTJ elements is reduced as described above. If the distance between the MTJ elements is reduced, one of the two adjacent MTJ elements is hidden behind the other MTJ element when the etching beams are greatly inclined so as to remove the re-deposition material from the side surface of each MTJ element. In this case, defective etching occurs and it is impossible to process each MTJ element into a desired pattern. Moreover, if the inclination of the etching beams is set smaller than the critical angle θcrt to prevent the adjacent MTJ elements from influencing each other, the re-deposition material remains on the side surface of each MTJ element. In this way, when the density of the MTJ elements on a plane layout increases, it is difficult to process the MTJ elements into desired patterns while suppressing the adhesion of the re-deposition material. Therefore, it is important to remove the re-deposition material from the side surface of each MTJ element and to process the MTJ elements at a high density in next-generation semiconductor devices and semiconductor manufacturing processes.

With reference to FIGS. 4A and 4B, the relation between an adjacent distance between the two MTJ elements and the critical angle θcrt of the etching beams is explained in more detail. Two MTJ elements (an MTJ1 and an MTJ2) adjacent to each other are provided on an underlying material 85. Hard masks HM are provided on the MTJ1 and MTJ2, respectively. The MTJ1 and the hard mask HM on the MTJ1 form a first structure 51, and the MTJ2 and the hard mask HM on the MTJ2 form a second structure 52. A plurality of structures 51 and 52 are formed on the semiconductor substrate 1 by the IBE into an array.

A reference angle θref is an inclination angle of a tangent from a lower end B1 of the first structure 51 to an upper end T2 of the second structure 52 adjacent to the first structure 51.

In other words, the reference angle θref is a maximum angle among angles at which ion beams toward the adjacent structures 51 and 52 can be irradiated onto the entire side surfaces of the respective structures 51 and 52.

When the incident angle of the ion beams is equal to or smaller than the reference angle θref, the ion beams can be irradiated onto the entire side surface of each structure without being intercepted by the other structure. It is thereby possible to irradiate the ion beams onto the underlying material 85 between the structures 51 and 52 until completion of processing of the structure 51 without the influence of the adjacent structure 52.

As shown in FIG. 4A, when the distance between the adjacent MTJ elements is sufficiently long, the reference angle θref is equal to or greater than the critical angle θcrt. When the reference angle θref is equal to or greater than the critical angle θcrt (45 degrees, for example), the irradiation angle of the ion beams can be set to be equal to or greater than the critical angle θcrt and equal to or smaller than the reference angle θref. In this case, the ion beams can be irradiated onto the entire side surface of the structure 51 without being intercepted by the adjacent structure 52. Furthermore, the ion beams can remove the re-deposition material on the side surface of the structure 51 while processing the structure 51. In this case, it suffices to prepare one ion gun for the etching apparatus. For example, the re-deposition material is the materials of the MTJ elements themselves or the underlying material 85 under the MTJ elements.

On the other hand, if the distance between the adjacent MTJ elements is reduced to follow the downscaling of MRAM chips as shown in FIG. 4B, the reference angle θref is smaller than the critical angle θcrt (45 degrees, for example). In this case, if the irradiation angle of the ion beams is set to be equal to or greater than the critical angle θcrt, the ion beams are intercepted by the adjacent structure 52. As a result, it is impossible to preferably process the MTJ element. If the irradiation angle of the ion beams is set to be equal to or smaller than the reference angle θref so that the ion beams are not intercepted by the adjacent structure 52, the irradiation angle of the ion beams is smaller than the critical angle θcrt and the side etching components of the ion beams decrease. Accordingly, the re-deposition material adhering to the side surface of the structure 51 partially remains without being completely removed. Therefore, if the materials of the MTJ element are to be processed by using only one ion gun (the first ion gun 20, for example), the MTJ element can not be processed into a desired shape or the re-deposition material remains on the side surface of the MTJ element.

Considering these problems, the etching apparatus 100 according to the first embodiment includes a plurality of ion guns 20 and 30 and processes the MTJ elements by using these ion guns 20 and 30.

A first irradiation angle θ1 of the first ion gun 20 is set to be equal to or smaller than the reference angle θref (about 45 degrees, for example), and a second irradiation angle θ2 of the second ion gun 30 is set to be equal to or greater than the critical angle θcrt (about 45 degrees, for example). By setting the first irradiation angle θ1 to be equal to or smaller than the reference angle θref, the ion beams IB1 from the first ion gun 20 can process materials 90 of each of the MTJ elements into a desired pattern. By setting the second irradiation angle θ2 to be equal to or greater than the critical angle θcrt, the ion beams IB2 from the second ion gun 30 can remove the re-deposition material on the side surface of the MTJ element. By simultaneously irradiating the ion beams IB1 and IB2 onto the materials 90 of the MTJ element, the MTJ element can be processed into a high density pattern while removing the re-deposition material on the side surface of the MTJ element.

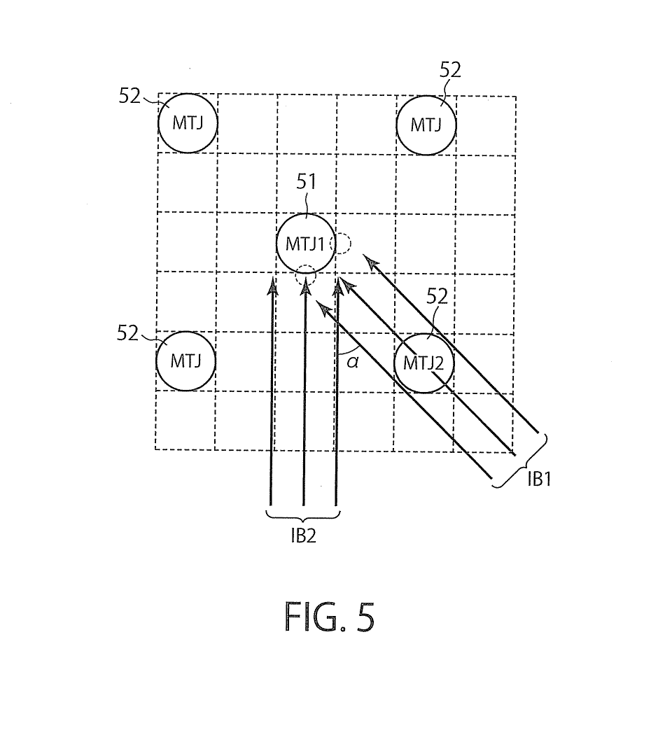

FIG. 5 is a plan view showing a layout of the MTJ elements and the hard masks HM and irradiating directions of the ion beams IB1 and IB2. The structures 51 and 52 including the MTJ elements and the hard masks HM are arranged two-dimensionally on the underlying material 85 into a matrix.

The relative angle α formed between the ion beams IB1 and IB2 is set to an angle at which the ion beams IB2 can effectively remove the re-deposition material adhering to the side surface of each MTJ element. The relative angle α is greater than 0 degree and equal to or smaller than 180 degrees. In FIG. 5, the relative angle α is set to about 45 degrees, for example.

When the first irradiation angle θ1 of the ion beams IB1 is close to the reference angle θref, the ion beams IB1 irradiated on a front surface of the structure 51 are not largely irradiated onto the underlying material 85 as shown in FIG. 5. Nevertheless, the ion beams IB1 are irradiated onto the underlying material 85 in portions adjacent to the front surface of the structure 51. As indicated by dashed circles in FIG. 5, therefore, the re-deposition material in large quantities adheres to side surface portions adjacent to the front surface of the structure 51. By setting the relative angle α to about 45 degrees, the ion beams IB2 are irradiated onto the side surface portions adjacent to the front surface of the structure 51 and can remove the re-deposition material adhering to the side surface portions.

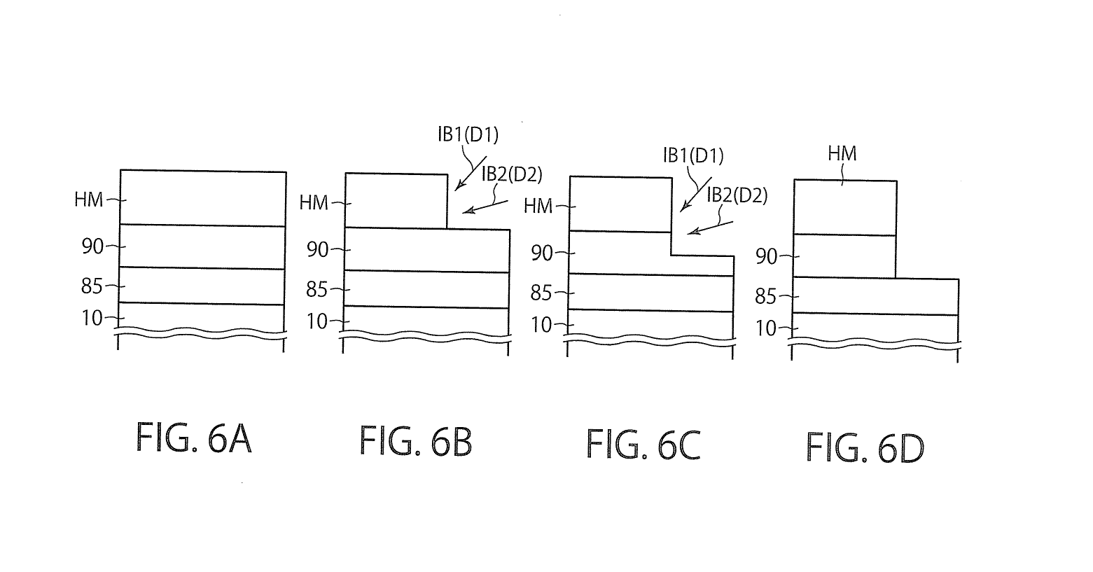

FIGS. 6A to 6D are cross-sectional views showing a formation flow of each of the MTJ elements using the etching apparatus 100 according to the first embodiment.

As shown in FIG. 6A, the underlying material 85 and the materials 90 of the MTJ element are deposited above the semiconductor substrate 1, and the hard mask HM is deposited on the materials 90 of the MTJ element. As shown in FIG. 6B, the hard mask HM is processed into a layout pattern of the MTJ element by lithography and either RIE (Reactive Ion etching) or the IBE. As shown in FIG. 6C, the etching apparatus 100 etches the materials 90 of the MTJ element by the IBE with the hard mask HM used as a mask. After the etching, processing on the MTJ element is completed as shown in FIG. 6D.

As shown in FIG. 6C, when the etching apparatus 100 etches the materials 90 of the MTJ element by the IBE, the first ion gun 20 irradiates the ion beams IB1 from a first direction D1 toward the semiconductor substrate 1 and, at the same time, the second ion gun 30 irradiates the ion beams IB2 from a second direction D2 toward the semiconductor substrate 1. The irradiation angle θ1 at which the first ion gun 20 irradiates the ion beams IB1 is set to be equal to or smaller than the reference angle θref, and the irradiation angle θ2 at which the second ion gun 30 irradiates the ion beams IB2 is set to be equal to or greater than the critical angle θcrt as described above.

In this way, the first ion gun 20 processes the materials 90 of the MTJ element by irradiating the ion beams IB1 from the first direction D1. At the same time, the second ion gun 30 etches away the deposited material adhering to the side surface of the MTJ element by irradiating the ion beams IB2 from the second direction D2.

With this configuration, the etching apparatus 100 according to the first embodiment can process the MTJ elements into the high-density layout patterns while removing the re-deposition material on the side surfaces of each of the MTJ elements by simultaneously using the first and second ion guns 20 and 30 even if the distance between the adjacent MTJ elements is short (or the aspect ratio of the MTJ elements is high).

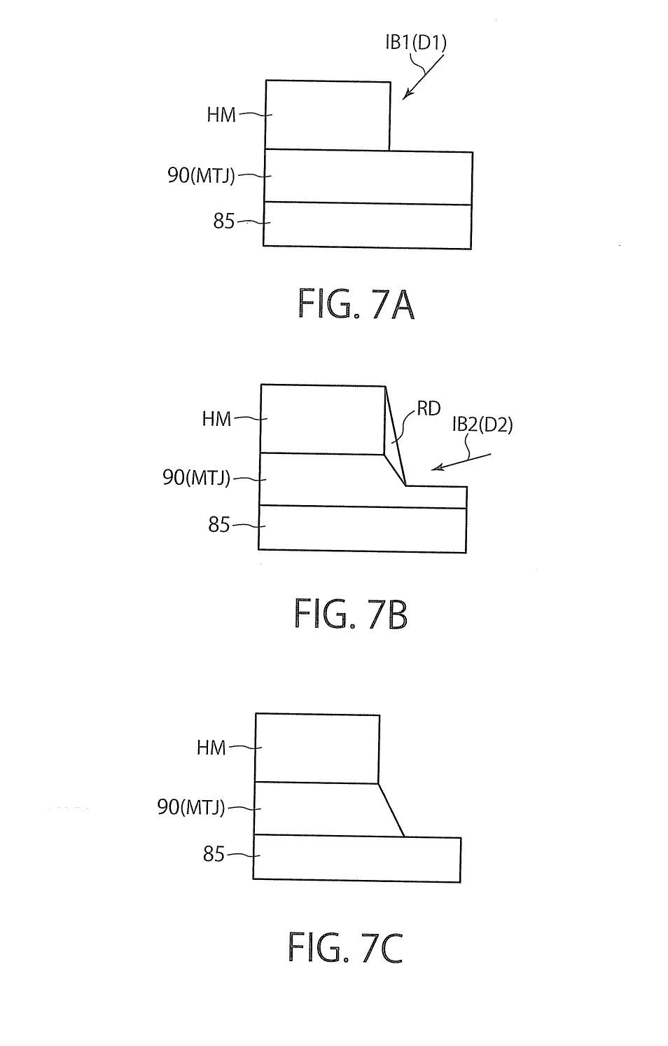

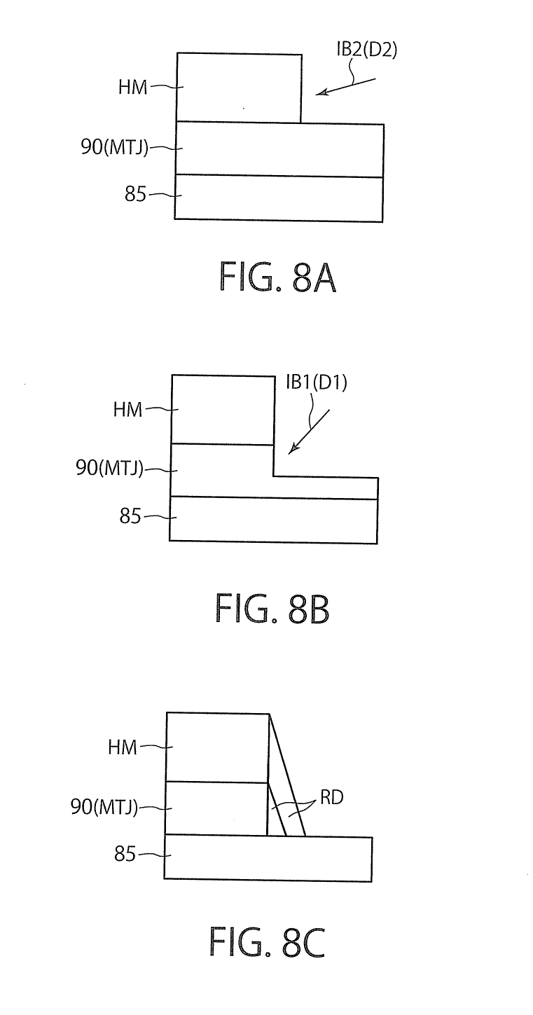

FIGS. 7A to 7C and 8A to 8C are cross-sectional views showing a formation flow of each MTJ element using an etching apparatus according to a comparative example. In this comparative example, the first ion gun 20 and the second ion gun 30 etch the materials 90 of the MTJ element at a different timing. In FIGS. 7A to 7C, after the first ion gun 20 processes the materials 90 of the MTJ element by irradiating the ion beams IB1 from the first direction D1, the second ion gun 30 processes the materials 90 of the MTJ element by irradiating the ion beams IB2 from the second direction D2. In FIGS. 8A to 8C, after the second ion gun 30 processes the materials 90 of the MTJ element by irradiating the ion beams IB2 from the second direction D2, the first ion gun 20 processes the materials 90 of the MTJ element by irradiating the ion beams IB1 from the first direction D1.

As shown in FIG. 7A, when the first ion gun 20 processes the materials 90 of the MTJ element by irradiating the ion beams IB1 from the first direction D1, the materials 90 of the MTJ element are etched while a re-deposition material RD adheres to the hard mask HM or the side surface of the MTJ element. The re-deposition material RD serves as a mask, and the layout pattern of the hard mask HM or the materials 90 of the MTJ element is made larger by as much as the re-deposition material RD. Therefore, as shown in FIG. 7B, the material 90 of the MTJ element is formed into a forward tapered shape so as to widen toward the underlying material 85. Next, as shown in FIG. 7B, the second ion gun 30 irradiates the ion beams IB2 onto the re-deposition material RD from the second direction D2. Although the re-deposition material RD is removed at this time, the MTJ element remains in a forward tapered shape as shown in FIG. 7C. In this case, a bottom of the MTJ element is made larger, which makes it impossible to form the MTJ elements into a desired layout pattern. This also hampers the downscaling of the MTJ elements.

As shown in FIG. 8A, when the second ion gun 30 processes the materials 90 of the MTJ element by irradiating the ion beams IB2 from the second direction D2, the re-deposition material RD does not adhere to the side surface of the MTJ element. However, because the side etching components of the ion beams IB2 are large in quantity, side surfaces of the hard mask HM and the materials 90 of the MTJ element are largely chipped off laterally as shown in FIG. 8B. Thereafter, as shown in FIG. 8C, the first ion gun 20 irradiates the ion beams IB1 onto the materials 90 of the MTJ element or the underlying material 85 from the first direction D1. At this time, the re-deposition material RD adheres to the side surfaces of the hard mask HM and the materials 90 of the MTJ element. This re-deposition material RD is left without being removed, which possibly causes short-circuit of the MTJ element.

In this way, if the first and second ion guns 20 and 30 irradiate the ion beams IB1 and IB2 at a different timing, it is difficult to form the MTJ element into a desired pattern or the re-deposition material RD remains.

On the other hand, in the etching apparatus 100 according to the first embodiment, the first and second ion guns 20 and 30 simultaneously irradiate the ion beams IB1 and IB2, the first irradiation angle θ1 at which the first ion gun 20 irradiates the ion beams IB1 is set to be equal to or smaller than the reference angle θref, the second irradiation angle θ2 at which the second ion gun 30 irradiates the ion beams IB2 is set to be equal to or greater than the critical angle θcrt, as explained above with reference to FIGS. 5 and 6A to 6D. This makes it possible to process the materials 90 of each of the MTJ elements while removing the re-deposition material deposited to the side surfaces of the hard mask HM and the MTJ element. This can relieve the forward tapered shape of the side surface of the MTJ element (make the side surface of the MTJ element sharp) while suppressing deposition of the re-deposition material on the side surface of the MTJ element. That is, it is possible to form the MTJ element into a desired layout pattern and to suppress the formation of the short pass on the side surface of the MTJ element.

### Second Embodiment

While the relative angle α formed between the ion beams IB1 and IB2 is set to about 45 degrees in the first embodiment, the relative angle α can be set arbitrarily so as to be able to efficiently remove the re-deposition material.

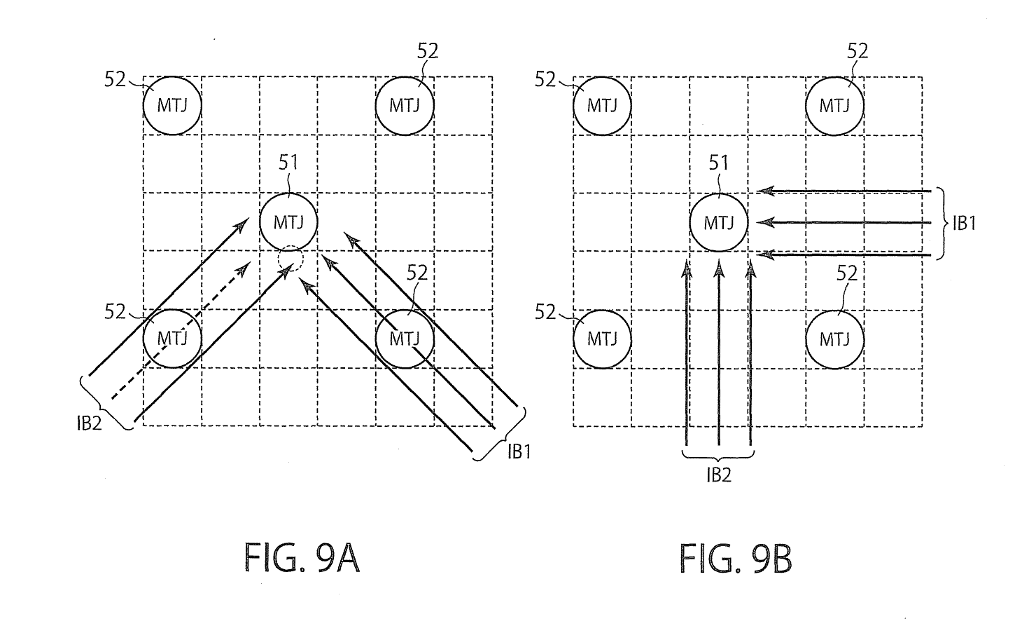

FIGS. 9A and 9B are plan views showing the layout of MTJ elements and hard masks HM and irradiating directions of the ion beams IB1 and IB2 according to a second embodiment. In the second embodiment, the relative angle α is set to about 90 degrees. The first irradiation angle θ1 at which the first ion gun 20 irradiates the ion beams IB1 can be set to be equal to or smaller than the reference angle θref similarly to the first embodiment. The second irradiation angle θ2 at which the second gun 30 irradiates the ion beams IB2 can be set to be equal to or greater than the critical angle θcrt similarly to the first embodiment.

As shown in FIG. 9A, when the ion beams IB1 and IB2 are irradiated in a direction from the structure 52 to the structure 51, the ion beams IB1 are not largely irradiated onto the underlying material 85 in a front surface portion of the structure 51. However, the ion beams IB1 are irradiated onto the underlying material 85 in a portion adjacent to the front surface of the structure 51 (a portion indicated by a dashed circle shown in FIG. 9A). Therefore, the re-deposition material adheres to the side surface portion adjacent to the front surface of the structure 51 in relatively large quantities.

On the other hand, as indicated by a dashed arrow shown in FIG. 9A, the ion beams IB2 are partially intercepted by the structure 52 adjacent to the structure 51. However, the ion beams IB2 are irradiated onto the side surface portions adjacent to the front surface of the structure 51 and can remove the re-deposition material.

As shown in FIG. 9B, when the ion beams IB1 and IB2 are not intercepted by the structures 52, both the ion beams IB1 and IB2 are sufficiently irradiated onto the structure 51. Therefore, although the ion beams IB1 cause the re-deposition material to adhere to the side surface of the structure 51, the ion beams IB2 can remove the re-deposition material. In this way, even if the relative angle α between the ion beams IB1 and IB2 is about 90 degrees, the second embodiment can achieve effects identical to those of the first embodiment.

### Third Embodiment

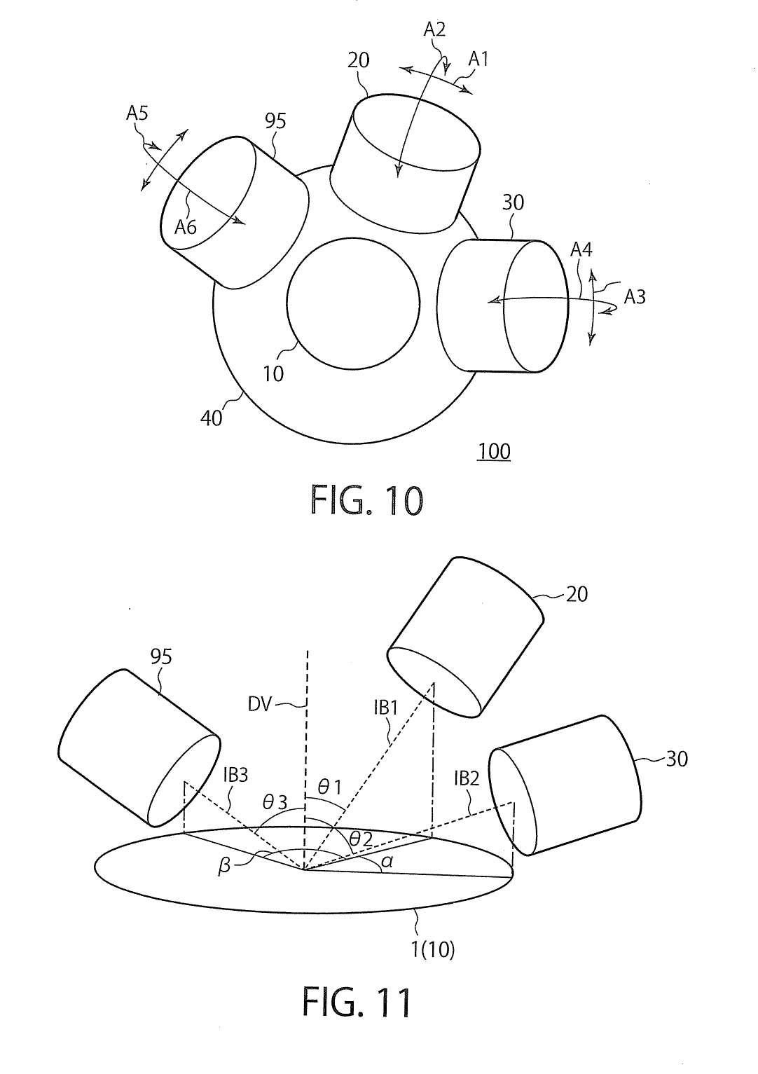

FIG. 10 is a schematic plan view showing the etching apparatus 100 as seen from above according to a third embodiment. The first and second ion guns 20 and 30 are configured as described with reference to FIG. 2. A third ion gun 95 is provided to be movable along the chamber 40 as indicated by arrows A5 and A6. The third ion gun 95 can thereby irradiate ion beams IB3 onto the semiconductor substrate 1 on the stage 10 from various directions. The third ion gun 95 can be configured similarly to the first and second ion guns 20 and 30.

FIG. 11 is a conceptual diagram showing a positional relation among the first to third ion guns 20, 30, and 95. The positional relation between the first ion gun 20 and the second ion gun 30 is already described above with reference to FIG. 3. The third ion gun 95 irradiates the etching beams IB3 onto the semiconductor substrate 1 from a third direction inclined at a third incident angle θ3 with respect to the vertical direction DV to the surface of the semiconductor substrate 1. The third incident angle θ3 can be set arbitrarily depending on the inclination angle of the stage 10 and a position of the third ion gun 95.

The third incident angle θ3 at which the third ion gun 95 irradiates the ion beams IB3 differs from the first incident angle θ1 at which the first ion gun 20 irradiates the ion beams IB1. Furthermore, it is assumed here that a relative angle formed between the projection of the first direction and that of the third direction is β when projecting the direction of the etching beam IB1 from the first ion gun 20 (the first direction) onto the semiconductor substrate 1 (or the stage 10) and the direction of the etching beam IB3 from the third ion gun 95 (a third direction) onto the semiconductor substrate 1 (or the stage 10).

The third incident angle θ3 and the relative angle β can be set arbitrarily. The third incident angle θ3 can be set depending on the inclination angle of the stage 10 and the direction of the third ion gun 95. The relative angle β can be set depending on relative positions of the first ion gun 20 and the third ion gun 95.

Furthermore, the first to third ion guns 20, 30, and 95 can set accelerating voltages and quantities of the etching beams IB1, IB2, and IB3 individually.

In the third embodiment, the first irradiation angle θ1 of the first ion gun 20 is set to be equal to or smaller than the reference angle θref (about 45 degrees, for example), and the irradiation angles θ2 and θ3 of the second and third ion guns 30 and 95 are set to be equal to or greater than the critical angle θcrt (about 45 degrees, for example). Note that the second and third irradiation angles θ2 and θ3 can be set either equally or differently. By setting the first irradiation angle θ1 to be equal to or smaller than the reference angle θref, the ion beams IB1 from the first ion gun 20 can process the materials 90 of each of the MTJ elements into a desired pattern. By setting the second and third irradiation angles θ2 and θ3 to be equal to or greater than the critical angle θcrt, the ion beams IB2 and IB3 from the second and third ion guns 30 and 95 can remove the re-deposition material on the side surface of the MTJ element. By simultaneously irradiating the ion beams IB1 to IB3 onto the materials 90 of the MTJ element, the MTJ element can be processed into a high density pattern while removing the re-deposition material on the side surface of the MTJ element.

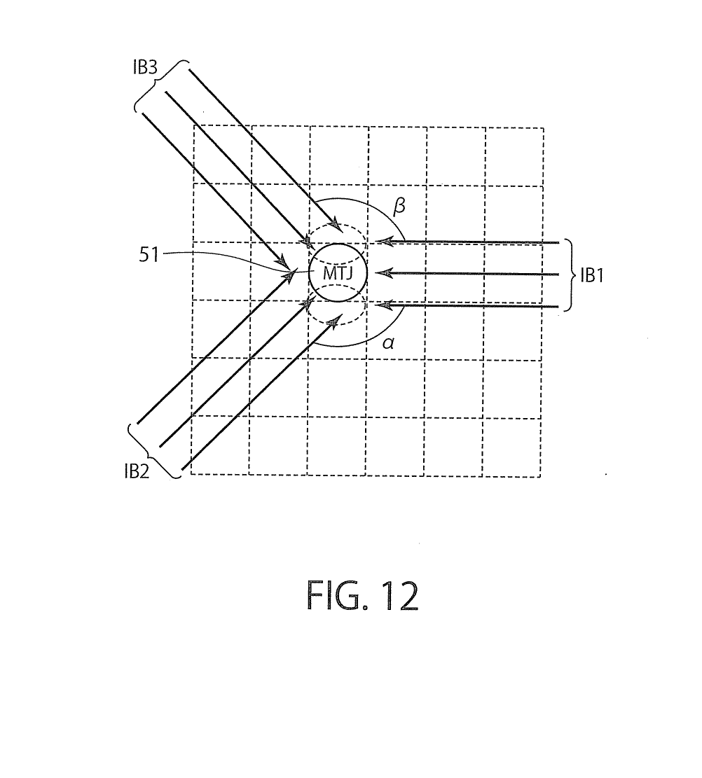

FIG. 12 is a plan view showing irradiating directions of the ion beams IB1 to IB3. In the third embodiment, the structure 51 including one MTJ element and one hard mask HM is arranged on the underlying material 85. The relative angles α and β are set to angles at which the ion beams IB2 and IB3 can effectively remove the re-deposition material adhering to the side surface of the MTJ element. The relative angles α and β are greater than 0 degree and equal to or smaller than 180 degrees. In FIG. 12, the relative angles α and β are respectively set to about ±135 degrees, for example.

When the first irradiation angle θ1 at which the first ion gun 20 irradiates the ion beams IB1 is equal to the reference angle θref (about 45 degrees, for example), the re-deposition material does not adhere to the front surface of the structure 51. However, the re-deposition material adheres to the side surface portions adjacent to the front surface of the structure 51 (portions indicated by dashed circles in FIG. 12). That is, even when the distance between the adjacent structures is sufficiently long as shown in FIG. 4A or only one structure 51 is formed as shown in FIG. 12, the re-deposition material possibly adheres to the side surface of the structure 51 if using only the ion beams IB1. Therefore, the etching apparatus 100 according to the third embodiment irradiates the ion beams IB2 and IB3 onto the side surface portions on both sides of the structure 51. The ion beams IB2 and IB3 are irradiated from directions opposite to each other across the ion beams IB1. That is, the relative angle α is set to +135 degrees with respect to the first direction whereas the relative angle β is set to −135 degrees with respect to the first direction. It is thereby possible to remove the re-deposition material adhering to the side surface portions on the both sides of the structure 51.

Needless to say, the etching apparatus 100 according to the third embodiment can be used at a time of forming a plurality of MTJ elements arranged two-dimensionally into a matrix as shown in FIG. 5 or FIGS. 9A and 9B. In this case, it suffices to set the relative angles α and β depending on the arrangement of the MTJ elements. For example, the relative angles α and β can be set to about ±45 degrees, about ±90 degrees, or about ±120 degrees.

In the etching apparatus 100 according to the third embodiment, the ion beams IB2 and IB3 from the second and third ion guns 30 and 95 can remove the re-deposition material adhering to the side surface portions by the ion beams IB1 from the first ion gun 20. Because the second and third ion beams IB2 and IB3 are irradiated onto the side surface portions on the both sides of the structure 51, it is possible to remove the re-deposition material more efficiently. Furthermore, the use of the etching apparatus 100 according to the third embodiment can dispense with a complicated manufacturing process for removing the re-deposition material adhering to the side surface portions on the both sides of the structure 51.

### (Modification)

In the first to third embodiments, the first to third ion guns 20, 30, and 95 can set the accelerating voltages and the quantities of the ion beams IB1 to IB3 to fixed voltages and fixed quantities. Alternatively, the first to third ion guns 20, 30, and 95 can change the accelerating voltages or the quantities of the ion beams IB1 to IB3 according to the rotation of the semiconductor substrate 1.

For example, in a case of a state shown in FIG. 9A, the accelerating voltages or the quantities of the ion beams IB1 and IB2 are set relatively high or large. In a case of a state shown in FIG. 9B, the accelerating voltages and/or the quantities of the ion beams IB1 and IB2 are set relatively low or small. In this way, by changing the accelerating voltages or the quantities of the ion beams IB1 and IB2 according to the rotation of the semiconductor substrate 1, the etching apparatus 100 can keep equilibrium between the adhesion of the re-deposition material and the removal of the re-deposition material more easily.

Each of the etching apparatus 100 according to the embodiments described above is for use in the processing of the MTJ elements included in the MRAM. Alternatively, each of these etching apparatus 100 can be used to process other memory elements. Moreover, each of the etching apparatus 100 can be used at a time of forming structures on the semiconductor substrate 1 by processing the semiconductor substrate 1 itself.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a stage capable of mounting a semiconductor substrate thereon;
a first irradiation part configured to irradiate an etching beam onto the semiconductor substrate from a first direction inclined at an arbitrary angle with respect to a vertical direction to a surface of the semiconductor substrate; and
a second irradiation part configured to irradiate an etching beam onto the semiconductor substrate from a second direction inclined at an arbitrary angle with respect to the vertical direction, wherein
the first and second irradiation parts simultaneously irradiate the etching beams when processing the semiconductor substrate or a material on the semiconductor substrate.

2. The apparatus of claim 1, wherein
the etching beam from the first irradiation part etches the semiconductor substrate or the material of the structure in order to form at least one structure on the semiconductor substrate, and
the etching beam from the second irradiation part etches a deposition material deposited to a side surface of the structure.

3. The apparatus of claim 1, wherein the first or second irradiation part is movable in order to be able to change the first or second direction and to be able to change a relative angle formed between the first direction and the second direction when projecting the first direction and the second direction onto the stage.

4. The apparatus of claim 1, wherein
the semiconductor manufacturing apparatus is used in order to form a plurality of structures above the semiconductor substrate,
the first direction is closer to the vertical direction than a direction of a tangent from a lower end of a first structure among the structures to an upper end of a second structure adjacent to the first structure, and
the second direction is either equal to the direction of the tangent or farther from the vertical direction than the direction of the tangent.

5. The apparatus of claim 2, wherein
the semiconductor manufacturing apparatus is used in order to form a plurality of structures above the semiconductor substrate,
the first direction is closer to the vertical direction than a direction of a tangent from a lower end of a first structure among the structures to an upper end of a second structure adjacent to the first structure, and
the second direction is either equal to the direction of the tangent or farther from the vertical direction than the direction of the tangent.

6. The apparatus of claim 3, wherein
the semiconductor manufacturing apparatus is used in order to form a plurality of structures above the semiconductor substrate,
the first direction is closer to the vertical direction than a direction of a tangent from a lower end of a first structure among the structures to an upper end of a second structure adjacent to the first structure, and
the second direction is either equal to the direction of the tangent or farther from the vertical direction than the direction of the tangent.

7. The apparatus of claim 4, wherein the second direction is equal to or greater than a critical angle, the critical angle being an irradiation angle of the etching beam when a deposition speed of a re-deposition material deposited to a side surface of the first structure is substantially equal to a removal speed of the re-deposition material removed from the side surface.

8. The apparatus of claim 2, wherein
the first direction is inclined at an angle smaller than 45 degrees with respect to the vertical direction, and
the second direction is inclined at an angle greater than 45 degrees with respect to the vertical direction.

9. The apparatus of claim 1, further comprising a third irradiation part configured to irradiate an etching beam from a third direction inclined at an arbitrary angle with respect to the vertical direction, wherein
the first to third irradiation parts simultaneously irradiate the etching beams when processing the semiconductor substrate or the material on the semiconductor substrate.

10. The apparatus of claim 9, wherein
the etching beam from the first irradiation part etches the semiconductor substrate or the material of the structure in order to form at least the structure on the semiconductor substrate, and
the etching beams from the second and third irradiation parts etch a deposition material deposited to a side surface of the structure.

11. The apparatus of claim 9, wherein
the first direction is inclined at an angle smaller than 45 degrees with respect to the vertical direction, and
the second and third directions are inclined at angles equal to or greater than 45 degrees with respect to the vertical direction.

12. The apparatus of claim 1, wherein each of the first and second irradiation parts changes an accelerating voltage or a beam quantity of the etching beam when processing the semiconductor substrate or the material on the semiconductor substrate.

13. The apparatus of claim 2, wherein the structure comprises an MTJ element.

14. A semiconductor device manufacturing method using a semiconductor manufacturing apparatus comprising a stage capable of mounting a semiconductor substrate thereon, a first irradiation part configured to irradiate an etching beam onto the semiconductor substrate, and a second irradiation part configured to irradiate an etching beam onto the semiconductor substrate, the semiconductor device manufacturing method comprising:
causing the first irradiation part to irradiate the etching beam onto a surface of the semiconductor substrate from a first direction inclined at an arbitrary angle with respect to a vertical direction to a surface of the semiconductor substrate; and
causing the second irradiation part to irradiate the etching beam onto the semiconductor substrate from a second direction inclined at an arbitrary angle with respect to the vertical direction simultaneously with irradiation of the first irradiation part.

15. The method of claim 14, wherein
the etching beam from the first irradiation part etches the semiconductor substrate or the material of the structure in order to form at least one structure on the semiconductor substrate, and
the etching beam from the second irradiation part etches a deposition material deposited to a side surface of the structure.

16. The method of claim 14, wherein
the semiconductor manufacturing apparatus is used in order to form a plurality of structures above the semiconductor substrate,
the first direction is closer to the vertical direction than a direction of a tangent from a lower end of a first structure among the structures to an upper end of a second structure adjacent to the first structure, and
the second direction is either equal to the direction of the tangent or farther from the vertical direction than the direction of the tangent.

17. The method of claim 15, wherein
the semiconductor manufacturing apparatus is used in order to form a plurality of structures above the semiconductor substrate,
the first direction is closer to the vertical direction than a direction of a tangent from a lower end of a first structure among the structures to an upper end of a second structure adjacent to the first structure, and
the second direction is either equal to the direction of the tangent or farther from the vertical direction than the direction of the tangent.

18. The method of claim 16, wherein the second direction is equal to or greater than a critical angle, the critical angle being an irradiation angle of the etching beam when a deposition speed of a re-deposition material deposited to a side surface of the first structure is substantially equal to a removal speed of the re-deposition material removed from the side surface.

19. The method of claim 14, wherein the apparatus further comprises a third irradiation part configured to irradiate an etching beam from a third direction inclined at an arbitrary angle with respect to the vertical direction, and
the first to third irradiation parts simultaneously irradiate the etching beams when processing the semiconductor substrate or the material on the semiconductor substrate.

20. The method of claim 19, wherein
the etching beam from the first irradiation part etches the semiconductor substrate or the material of the structure in order to form at least the structure on the semiconductor substrate, and
the etching beams from the second and third irradiation parts etch a deposition material deposited to a side surface of the structure.
